(19) United States
(12) Patent Application Publication
(10) Pub. No.: US 2002/0000656 A1
(43) Pub. Date: Jan. 3, 2002

(54) BALL GRID ARRAY PACKAGE AND A PACKAGING PROCESS FOR SAME

(76) Inventors: CHIEN-PING HUANG, HSINCHU HSIEN (TW); TZONG-DAR HER, TAICHUNG (TW)

Correspondence Address: J C PATENTS INC, 4 VENTURE, SUITE 250, IRVINE, CA, 92618, US

(21) Appl. No.: 09/451,135

(22) Filed: Nov. 30, 1999

(51) Int. Cl. H01L 29/40; H01L 23/52; H01L 23/48

(52) U.S. Cl. 257/736

(57) ABSTRACT

A ball grid array package and its packaging process is described. A thermal dissipation substrate has a first surface and a second surface. An insulating layer and a copper foil are built up sequentially on the second surface. The copper foil is patterned to form multiple of conducting wire traces, and then a solder resist is coated on the surfaces of both the conducting wire traces and the insulating layer. Afterwards, part of the surfaces of the conducting wire traces is exposed to form multiple bonding fingers and multiple ball pads. Moreover, an aperture is formed at the center of the thermal dissipation substrate and insulating layer to penetrate through the thermal dissipation substrate and the insulating layer. Furthermore, a chip having its active surface bound to the first surface and has multiple bonding wires passing through the aperture to electrically connect the bonding pads to bonding fingers. Finally, encapsulating material is employed to encapsulate the chip, the bonding wires and the bonding fingers, and the solder balls are placed on the respective ball pads.

### BACKGROUND OF THE INVENTION

1. Field of the Invention

This invention relates to a ball grid array package and its packaging process, and more particularly to a ball grid array package having a highly efficient thermal dissipation ability and a low cost, and a packaging process for the same.

2. Description of Related Art

Following the rapid development of high technology and the demand for a great amount of information circulation, our daily life has become closely related to the integrated circuit devices. As far as the development of the semiconductor technology is concerned, since the degree of integration of the electronic devices is raising, many more semiconductor devices can be accommodated in a single, tiny chip. As operating speed is continuously increasing, consequently, the required number of leads for each of the integrated circuit device is also increasing. Nevertheless, the new challenges not only need to meet the requirements of being light, thin, short, and small in dimension, but also need to resolve problems such as thermal dissipation and electromagnetic interference at high frequency.

Shown in FIG. 1 is the cross-sectional view of the conventional ball grid array package of the “center pad” structure fabricated. The ball grid array (BGA) package of the “center pad” structure is fabricated on a laminated board 100 including an insulating resin core layer 102 such as Bismaleimide-Triazine (BT) and copper foil 104 wherein the copper foil 104 forms multiple strips of conductive trace after being patterned. The surface of copper foil 104 is covered with a solder resist 120 and only bonding fingers 116 for bonding wires and ball pads 118 for placing solder balls 122 are exposed. The chip 106 includes an active surface 108a and a back surface 108b wherein the active surface 108a includes multiple bonding pads 110. The active surface 108a, facing the laminated board 100, of chip 106 is attached to the laminated board by, for example, an adhesive tape 112 sticking to the insulating resin core layer 102. In the “center pad” structure, the bonding pad 110 is disposed at the center of the chip 106 and is electrically connected to the respective bonding fingers 116 in the copper foil 104 through the bonding wires 114. The encapsulating material 124 encapsulates the connecting parts of the chip 106 and the laminated board 100, the bonding wires 114, and the bonding fingers 116. The solder balls 122 used as connecting ports connecting to other devices such as a circuit board (not shown) are placed at the ball pads 118

In the conventional ball grid array package of the “center pad” structure, the active surface 108a that is filled with semiconductor devices is stuck to the insulating resin core layer 102 through the adhesive tape 112. Since the active surface 108a is a main heat source of a semiconductor circuit device and the insulating resin core layer 102 is unable to provide any route to dissipate heat, consequently, its thermal dissipation efficiency is low and device performance will be affected. Furthermore, using BT material for the insulating resin core layer 102 not only cannot provide a good route for thermal dissipation, but also cannot lower the cost of the product because the price of BT is rather high.

### SUMMARY OF THE INVENTION

It is therefore an objective of the present invention to provide a ball grid array package having a high thermal dissipation efficiency and a packaging process for the same,. The package structure makes use of a thermal dissipation plate as a packaging substrate, which thermal dissipation plate is directly bound to the chip's active surface so as to improve the thermal dissipation efficiency and further to raise the device's performance.

It is another objective of the present invention to provide a ball grid array package and a packaging process for the same, such that besides having the chip's active surface directly bound to the thermal dissipation plate, the thermal dissipation plate can also be grounded to improve the device's electrical performance.

Yet another objective of the present invention is to provide a ball grid array package and packaging process for the same, in which a thermal dissipation plate is substituted for the insulating resin core layer, which not only can improve the device's performance but also can lower the production cost, as well.

In order to attain the foregoing objectives, the present invention provides a ball grid array packaging process. First, the present invention provides a thermal dissipation substrate having a first surface and a second surface. Then, alternating layers of an insulating layer and a patterned copper foil layer are built up on the second surface. Then, the copper foil is patterned in order to form multiple conductive traces. Moreover, a solder resist is coated on the surface of the patterned copper foil and on the surface of the insulating layer. A part of the surface of the conductive traces is exposed in order to form multiple bonding fingers and multiple ball pads. Thereafter, an aperture is formed at the center of the thermal dissipation substrate and the insulating layer. Next, a chip having an active surface and a back surface is provided, in which the active surface of the chip is bound to the first surface. The bonding pads are then electrically connected to the bonding fingers by multiple bonding wires passing through the aperture. Finally, the chip, the bonding wires, and the bonding fingers are encapsulated in an encapsulating material, and the solder balls are placed at the respective ball pads.

As for the ball grid array package, the present invention provides a thermal dissipation substrate having a first surface and a second surface, an aperture at its center, and having insulating layers and copper foils alternately build up on the second surface. The copper foil is then patterned in order to form multiple conductive traces. Moreover, a solder resist is coated on the conductive traces and on the surface of the insulating layer while exposing part of the surface of the conductive traces in order to form multiple bonding fingers and ball pads. Thereafter, a chip having an active surface and a back surface is provided, in which the active surface of the chip is bound to the first surface. The bonding pads are then electrically connected to the bonding fingers by multiple bonding wires passing through the aperture. Finally, the chip, the bonding wires, and the bonding fingers are encapsulated with an encapsulating material, and the solder balls are placed on the respective ball pads.

According to a preferred embodiment of the present invention, for the integrated circuit with high number of leads, the thermal dissipation substrate can alternately build up multiple layers of insulating layer and patterned copper foil on the second surface of the substrate. A relatively complicated circuit is then formed through the via in the insulating layer. Moreover, by the via penetrated through the thermal dissipation substrate and the insulating layer, a thermal dissipation substrate ground that can further improve the electrical performance of the integrated circuit is created. Furthermore, a plating layer can be formed on the surface of each of the ball pads and each of the bonding fingers in order to improve the bondabilty to the bonding wires or the solderability to the solder balls.

### BRIEF DESCRIPTION OF DRAWINGS

The objectives, characteristics, and advantages of the present invention can be more fully understood by reading the following detailed description of the preferred embodiments, with reference made to the accompanying drawings as follows:

FIG. 1 is a cross-sectional view of the ball grid array package of the “center pad” structure fabricated according to the prior art.

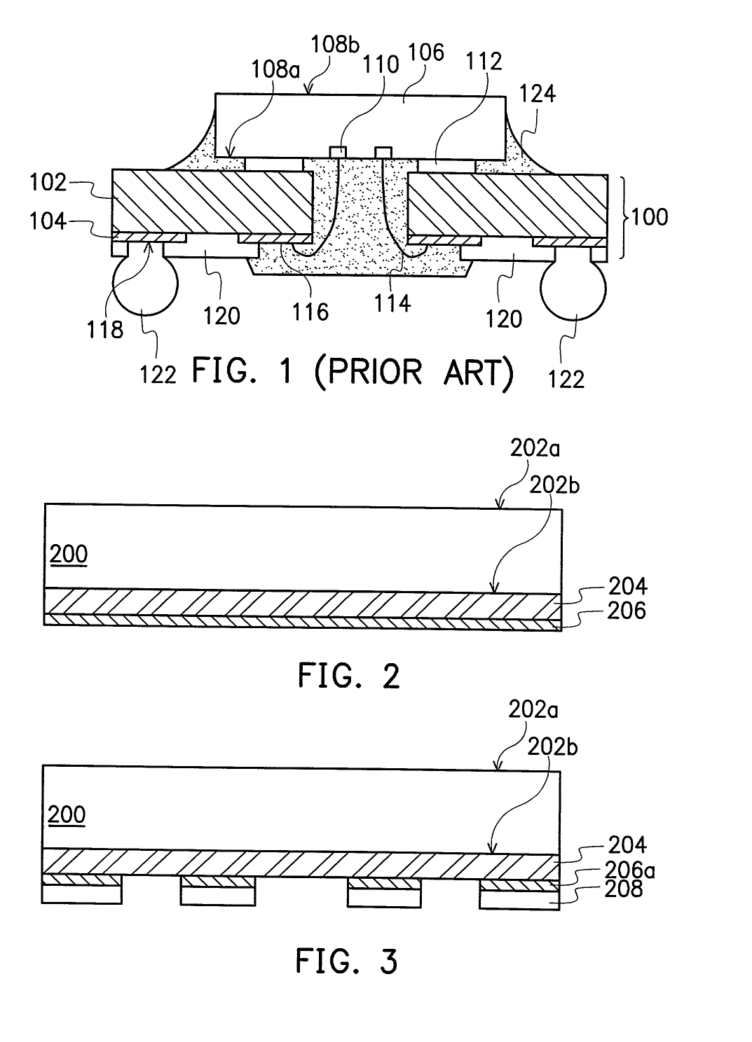

FIG. 2 to FIG. 7 are the schematic cross-sectional views illustrating the packaging process of a ball grid array in accordance with a preferred embodiment of the present invention.

FIG. 8 is a schematic cross-sectional view of a ball grid array package fabricated in accordance with another preferred embodiment of the present invention.

FIG. 9 is a schematic cross-cross-sectional view of a ball grid array package fabricated in accordance with one other preferred embodiment of the present invention.

### DETAILED DESCRIPTION OF PREFERRED EMBODIMENT

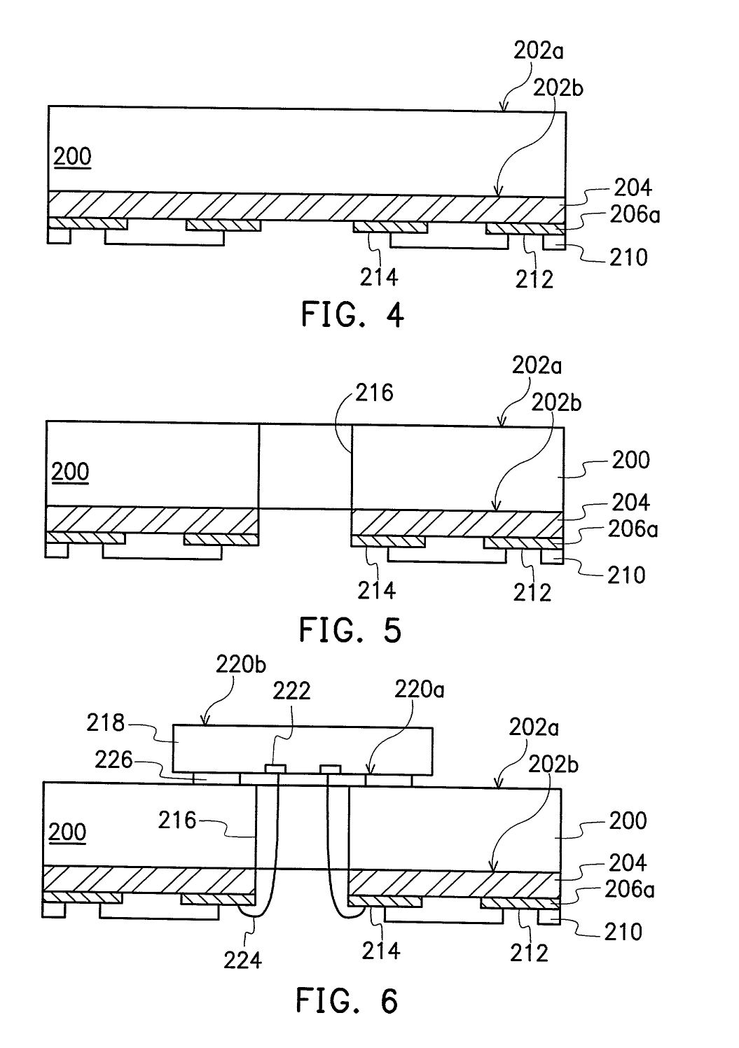

Shown in FIG. 2 to FIG. 7 are the schematic cross-sectional views illustrating the packaging process of a ball grid array in accordance with a preferred embodiment of the present invention. In FIG. 2, a thermal dissipation substrate 200 having a first surface 202a and a second surface 202b is provided. The thermal dissipation substrate 200 is made of a metal material such as copper, etc. having good heat conduction. On the second surface 202b, an insulating layer 204 and a copper foil 206 are sequentially built up. The material of the insulating layer 204 includes prepreg such as FR-4 and FR-5, Bismaleimide-Triazine (BT) or epoxy. The insulating layer 204 and the copper foil 206 can be built up on the thermal dissipation substrate 200 by pressing. The insulating layer 204 can also be formed on the second surface 202b by coating while the copper foil 206 can also be formed by plating or electroless plating. In order to enhance the bonding effect between the second surface 202b of the thermal dissipation substrate 200 and the insulating layer 204, an oxidization process can be performed first to form a coarse surface.

As shown in FIG. 3, a general photolithography and etching process can be employed to perform the patterning process on the copper foil 206 (shown in FIG. 2). The copper foil 206 is patterned by first coating it with a photo-resist layer or photosensitive dry film followed by an exposure and a development process. Subsequently, an etching process is performed while using photo-resist 208 layer as etching mask and by using copper chloride (CuCl₂) and hydrogen peroxide (H₂O₂) as an etching solution to form multiple trace lines 206a. Thereafter, the photo-resist 208 layer is stripped.

Subsequently, as shown in FIG. 5, an aperture 216 is formed at the center of and penetrating through the thermal dissipation substrate 200 and the insulating layer 204. The bonding fingers 214 are positioned at the periphery of the aperture 216.

Then, as shown in FIG. 6, a die attaching and a wire bonding process is performed. The chip 218 possesses an active surface 220a and a back surface 220b, where the active surface 220a has a set-up of multiple bonding pads 222. As the chip of a “center pad” is employed, the bonding pads 222 are disposed at the center of the chip 218. The chip 218 has its active surface 220a bound to the first surface 202a of the substrate 200 through the thermal conductive adhesive material 216 such as thermal conductive insulating gel. Bonding wires 224 made of a material such as aluminum or gold are then passed through the aperture 216 to electrically connect to the bonding pads 222 and the bonding fingers 214, respectively.

FIG. 7 illustrates the process of encapsulation and ball placement. Encapsulating material such as epoxy or liquid compound is employed to encapsulate the chip 218, the bonding wires 224, and the bonding fingers 214. Screen printing, dispensing or transfer molding can be employed for the encapsulating process. The encapsulating process can be performed by covering the back surface 220b of the chip 218 or simply exposing the back surface 220b in order to attain a good thermal dissipation effect. Solder balls 230 made of material such as Lead-Tin alloy are then placed on the ball pads 230 to be used as connecting ports.

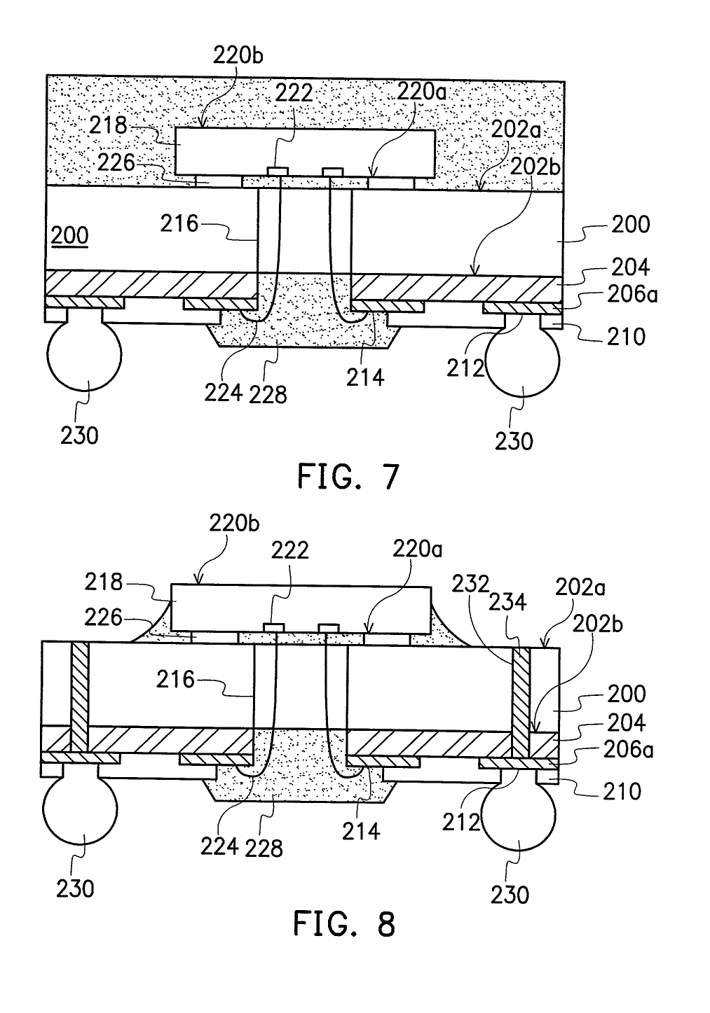

FIG. 8 is a schematic cross-sectional view of a ball grid array package in accordance with another preferred embodiment of the present invention. In this embodiment, the way that the chip 218 has its active surface 220a bound to the thermal dissipation substrate 200 can greatly improve the thermal dissipation effect for the integrated circuit devices. In addition, the thermal dissipation substrate 200 can be grounded to improve the electrical performance of the above-mentioned devices. As shown in FIG. 8, the thermal dissipation substrate 200 can be grounded by connecting to the traces 206a and solder balls 230 through the via 232. The via 232 is formed by drilling through the insulating layer 204, the copper foil 206 (shown in FIG. 2), and the thermal dissipation substrate 200 after they are built up. Thereafter, the via 232 is filled with conductive material such as plating copper, silver paste, etc. to electrically connect the thermal dissipation substrate 200 and copper foil 206. The subsequent patterning process of the copper foil 206 also electrically connects the thermal dissipation substrate 200 and the trace 206a, and both the substrate 200 and the trace 206a are grounded through the solder balls 230.

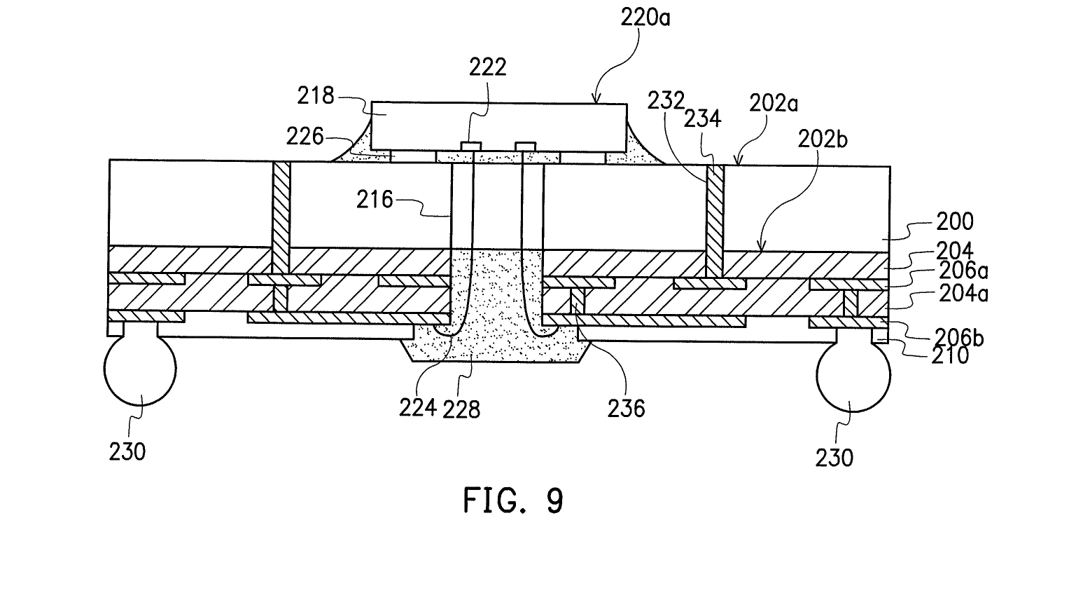

Although the foregoing embodiment provides only an example with a layer of trace, a build-up of multiple layers of trace can be performed to form multiple wire connection in order to meet the wire layout requirements for devices having a high pin count. FIG. 9 is a schematic cross-sectional view of a ball grid array package in accordance with one other preferred embodiment of the present invention. As shown in FIG. 9, the thermal dissipation substrate 200 can have on its second surface 202b alternately built-up multiple layers of 204, 204a and patterned copper foil layers 206a, 206b. Among them, the insulating layer 204 is adjacent to the second surface 202b and the patterned copper foil becomes the outer built-up surface. The patterned copper foil layer 206a, 206b forms traces that are electrically connected through the via 216. The multi-layer build-up of insulating layers, patterned copper foil, and via can be achieved by an accompanying photolithography or a screen printing process. All other processes such as the via formation, the solder resist coating, the chip bonding, and the wire bonding are similar to the above-mentioned embodiments, and thus are not repeated here.

To summarize the foregoing statement, the present invention comprises at least the following advantages:

1. The ball grid array package and a packaging process for the same of the present invention can form a package capable of highly efficient heat dissipation. This is due to the fact that the present invention directly bonds a thermal dissipation substrate to the active surface of the chip such that the heat accumulated in the chip can be transferred out efficiently. Consequently, the device's performance can be improved.

2. The ball grid array package and a packaging process for the same of the present invention can improve the device electrical properties. This is due to the fact that not only does the chip have its active surface directly bound to the thermal dissipation substrate, but also that the thermal dissipation substrate can be grounded through the conducting traces and the solder balls.

3. The ball grid array package and a packaging process for the same of the present invention can provide sufficient rigidity for the package structure since the present invention employs the thermal dissipation substrate as a substitute for the insulating resin core layer of the prior art.

The invention has been described using an exemplary preferred embodiment. However, it is to be understood that the scope of the invention is not limited to the disclosed embodiment. On the contrary, it is intended to cover various modifications and similar arrangements. The scope of the claims, therefore, should be accorded the broadest interpretation so as to encompass all such modifications and similar arrangements.

What is claimed is:

1. A ball grid array packaging process, comprising:
providing a thermal dissipation substrate, the thermal dissipation substrate having a first surface and a second surface;
building up alternating layers on the second surface, the alternating layers at least comprising an insulating layer and a patterned copper foil layer, to form a built-up layer, wherein the insulating layer is adjacent to the second surface and the patterned copper foil layer is positioned on an outer surface of the built-up layer;
coating a solder resist on a surface of the patterned copper foil and on a surface of the insulating layer, and then exposing a part of the surface of the patterned copper foil to form at least a plurality of bonding fingers and a plurality of ball pads;
forming an aperture at the center of the thermal dissipation substrate and the insulating layer;
providing at least a chip having an active surface and a back surface, wherein the active surface has a plurality of bonding pads and the active surface of the chip is bound to the first surface of the thermal dissipation substrate;
electrically connecting the bonding pads to the bonding fingers by a plurality of bonding wires passing through the aperture;
encapsulating the chip, the bonding wires, and the bonding fingers in an encapsulating material; and
placing the solder balls on respective ball pads.

2. The ball grid packaging process of claim 1, wherein the second surface has alternately built-up layer of the insulating layers and the patterned copper foil layers, wherein one of the insulating layers is adjacent to the second surface and one of the copper foil layers is on the outer surface of the built-up layer, and wherein a plurality of conductive vias for electrically connecting the patterned copper foil is set up between the insulating layers.

3. The ball grid packaging process of claim 1, wherein a process to alternately stack up a layer of the insulating layers and the patterned copper foil layers on the second surface further comprises:
forming at least a via to penetrate through the thermal dissipation substrate, the insulating layer, and the copper foil layer; and
passing an conductive material through the via for electrically connecting the thermal dissipation substrate to the bonding fingers.

4. The ball grid packaging process of claim 3, wherein the thermal dissipation substrate is grounded through one of the bonding fingers and through one of the solder balls.

5. The ball grid packaging process of claim 1 wherein after coating the solder resist onto the patterned copper foil and insulating layer surfaces, the process further comprises forming a plating layer on the bonding fingers and on the ball pads.

6. The ball grid packaging process of claim 5 wherein a material of the plating layer is selected from a group consisting of copper, nickel, silver, palladium, palladium-nickel alloy, gold, and a combination thereof.

7. The ball grid packaging process of claim 1 wherein the method of forming the aperture comprises hole-punching.

8. The ball grid packaging process of claim 1 wherein the method of forming the aperture comprising etching.

9. A ball grid array package comprising:
a thermal dissipation substrate having a first surface, and a second surface, and having an aperture at a center of the thermal dissipation substrate;
at least an insulating layer and a patterned copper foil layer being alternately built up on the second surface to form a built-up layer, wherein the insulating layer is adjacent to the second surface and the patterned copper foil layer is positioned on an outer surface of the built-up layer;
a solder resist coating on a surface of the patterned copper foil and on a surface of the insulating layer, and exposing a part of the surface of the patterned copper foil to form at least a plurality of bonding fingers and a plurality of ball pads;
at least a chip having an active surface and a back surface, wherein the active surface has a plurality of bonding pads, the active surface of the chip is bound to the first surface of the thermal dissipation substrate, and the bonding pads are positioned at a periphery of the aperture;
a plurality of bonding wires electrically connecting the bonding pads to the bonding fingers by passing through the aperture;
an encapsulating material encapsulating the chip, the bonding wires, and the bonding fingers; and
a plurality of solder balls disposed respectively on the ball pads.

10. The ball grid package of claim 9, wherein the second surface has an alternately built-up layer of the insulating layers and the patterned copper foil layers, wherein one of the insulating layers is adjacent to the second surface and one of the copper foil layers is on the outer surface of the built-up layer, and wherein a plurality of conductive vias for electrically connecting the patterned copper foil is set up between the insulating layers.

11. The ball grid package of claim 9 wherein the thermal dissipation substrate further comprises:
at least a via penetrating through the thermal dissipation substrate, the insulating layer and the copper foil layer; and
a conducting material passing through the via for electrically connecting the thermal dissipation substrate to the patterned copper foils.

12. The ball grid package of claim 11, wherein the thermal dissipation substrate is grounded through one of the conductive traces and through one of the solder balls.

13. The ball grid package of claim 9, wherein each of the bonding fingers and each of the ball pads further comprises a plating layer.

14. The ball grid package of claim 13 wherein a material of the plating layer is selected from a group consisting of copper, nickel, silver, palladium, palladium-nickel alloy, gold, and a combination thereof.

15. The ball grid package of claim 9, wherein the encapsulating material exposes the back surface of the chip.
